(19) United States
(12) Patent Application Publication
(10) Pub. No.: US 2026/0005053 A1
(43) Pub. Date: Jan. 1, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Kai-Chieh CHANG, Changhua (TW); Che-Chang HSU, Taichung City (TW); Kai-Fa HO, New Taipei City (TW); Li-Jui CHEN, Hsinchu City (TW)

(73) Assignee: TAIWAN SEMICONDUCTOR MANUFACTURING COMPANY, LTD., Hsinchu (TW)

(21) Appl. No.: 18/758,214

(22) Filed: Jun. 28, 2024

(51) Int. Cl. H01L 21/677; B65G 47/90

(52) U.S. Cl. CPC H01L 21/67736; B65G 47/90; H01L 21/67724; H01L 21/6773; H01L 21/67733

(57) ABSTRACT

A method includes retrieving a first front opening unified pod (FOUP) from a FOUP stocker utilizing an interface module equipped with a transfer module; transporting the retrieved first FOUP via the transfer module across a first path within the interface module to align the first FOUP with an available first load port of a process tool; loading the first FOUP on the first load port; delivering wafers from the first FOUP to the process tool via the first load port to initiate a wafer processing operation using the wafers.

### BACKGROUND

Semiconductor integrated circuit fabrication facilities (“fabs”) are highly automated. Movement of semiconductor wafers between various process tools is accomplished by an automated material handling system (AMHS). The wafers can be transported through the fab in Front Opening Unified Pods (FOUPs). A FOUP is a specialized enclosure designed to hold semiconductor wafers securely and safely in a controlled environment, and to allow the wafers to be removed for processing or measurement by tools equipped with appropriate load ports and robotic handling systems. Fins in the FOUP hold the wafers in place, and a front opening door allows robot handling mechanisms to access the wafers directly from the FOUP. A FOUP can be located on a load port, and can be manipulated by the AMHS. The AMHS transport vehicles travel relatively long distances to carry the FOUPs between tools that perform different fabrication processes. The tools may be located within different portions of the same building, or in different buildings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a fabrication facility in accordance with some embodiments of the present disclosure.

FIGS. 2A-2E illustrate schematic views of an overhead transport vehicle (OHT) system with a stocker and a process tool in accordance with some embodiments of the present disclosure.

FIGS. 3A-3E illustrate schematic views at least one stocker combined with at least one process tool in accordance with some embodiments of the present disclosure.

FIG. 4 is flowchart of a method of operating the systems shown in FIGS. 1-3E in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

To reduce costs in semiconductor manufacturing processes, the development of process tools has increasingly focused on achieving higher throughputs (e.g., in lithography scanners). However, the same slow speeds of FOUP carriers and an insufficient number of in-process FOUP slots have become major productivity bottlenecks. Combining less-than-full lots (e.g., fewer than 25 pieces) into fully utilized FOUPs (e.g., 25 pieces) can enhance carrier efficiency. However, this approach applies additional sorters (i.e., tools for merging wafers), introducing complexities that increase the risk of queuing time (i.e., Q-time) concerns. Furthermore, the merging process involves complex logistics to prevent contamination, necessitating careful consideration of wafer product type, wafer status, tool type, and FOUP type. These factors contribute to low merging efficiency and continue to constrain carrier speed.

Therefore, the present disclosure in various embodiments provides a method to integrate a FOUP stocker with a high-throughput process tool, which can address the long-standing challenges of slow FOUP carrier speeds and insufficient in-process FOUP slots, facilitating direct wafer transfers via conveyor belts or robotic arms, thus bypassing slower carrier systems. The integration can have adjustable FOUP slots that dynamically serve as buffers, adapting in real-time to match production needs, and allows multiple process tools to share FOUP stockers, optimizing space and resources in the facility. Hence, this system can reduce wait times for wafer transfers, increase throughput from more in/out ports, and enhance flexibility with tunable FOUP slots and the ability to quickly supply wafers to process tools. Additionally, the system can maintain more wafers in process, handle different wafer types simultaneously, and allows for a flexible fab layout design.

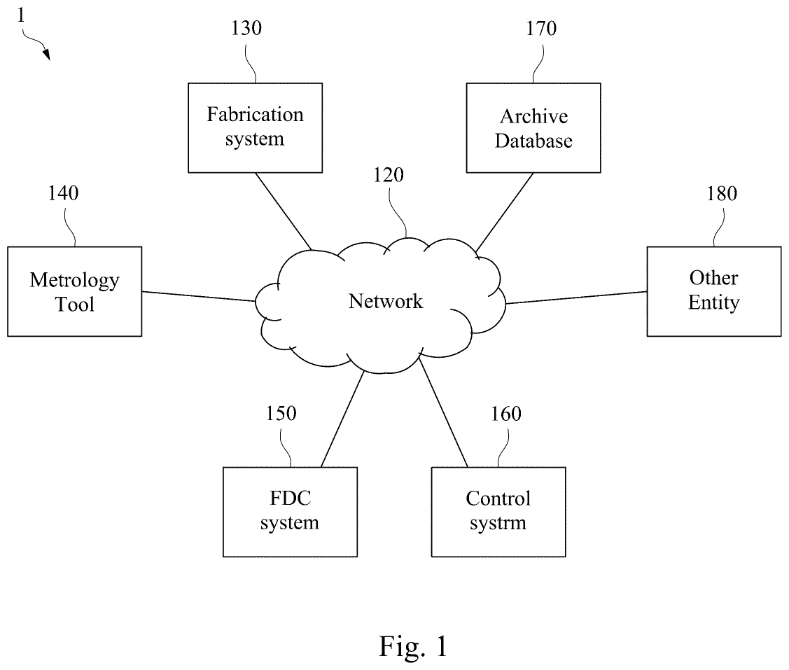

Reference is made to FIG. 1. FIG. 1 is a block diagram of a fabrication facility in accordance with some embodiments of the present disclosure. The fabrication facility 1 implements integrated circuit manufacturing processes to fabricate integrated circuit devices. For example, the fabrication facility 1 may implement semiconductor manufacturing processes that fabricate semiconductor wafers. It should be noted that, in FIG. 1, the fabrication facility 1 has been simplified for the sake of clarity to better understand the inventive concepts of the present disclosure. Additional features can be added in the fabrication facility 1, and some of the features described below can be replaced or eliminated in other embodiments of the fabrication facility 1. The fabrication facility 1 may include more than one of each of the entities. In some embodiments, and may further include other entities not illustrated in the depicted embodiment.

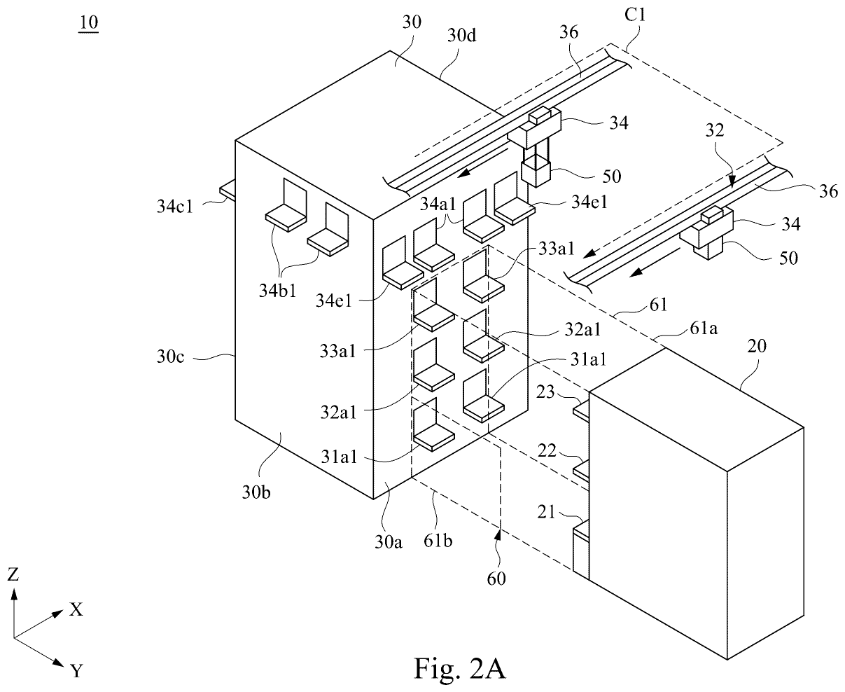

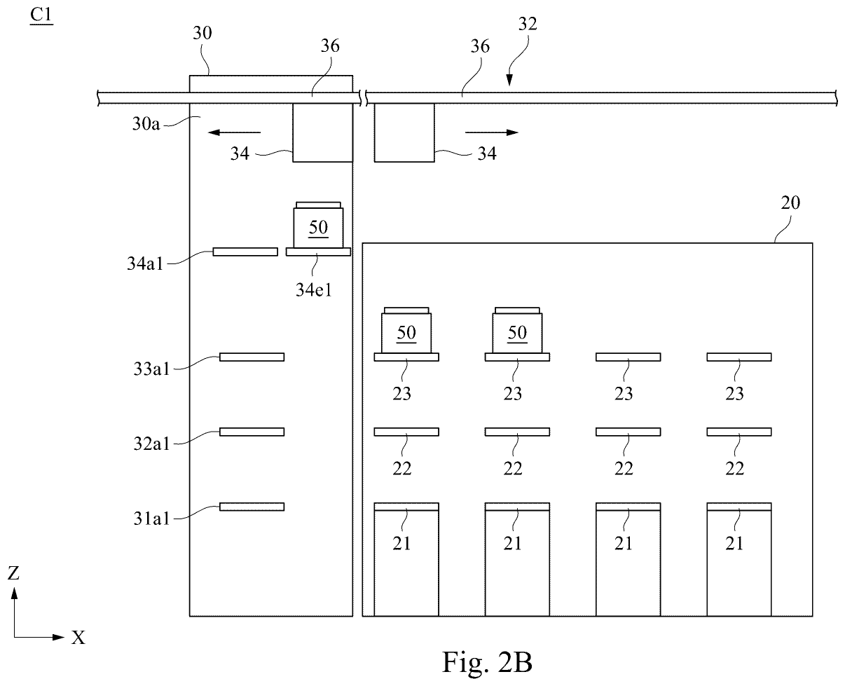

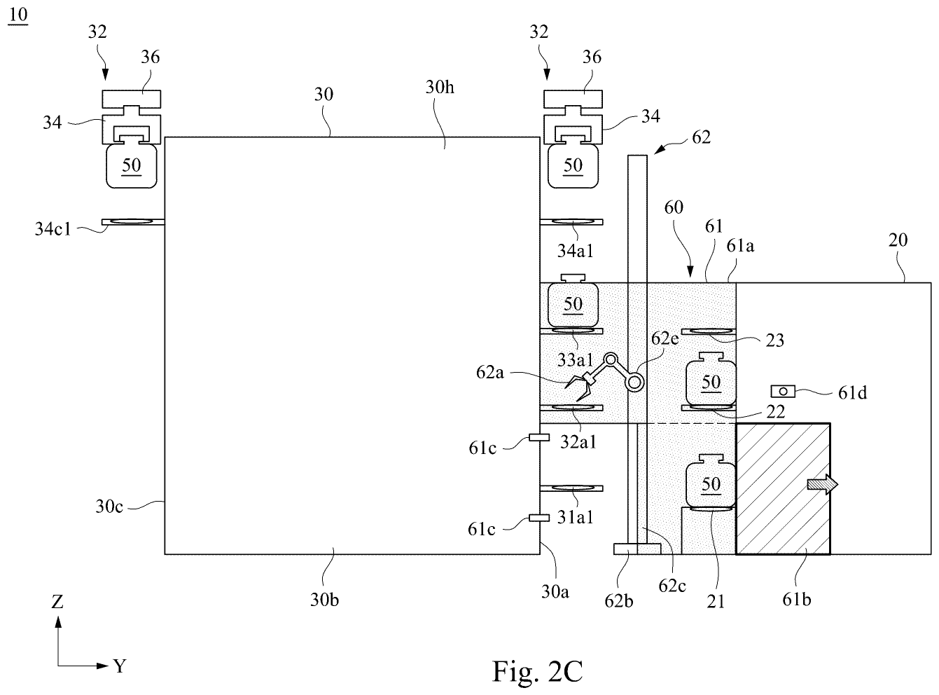

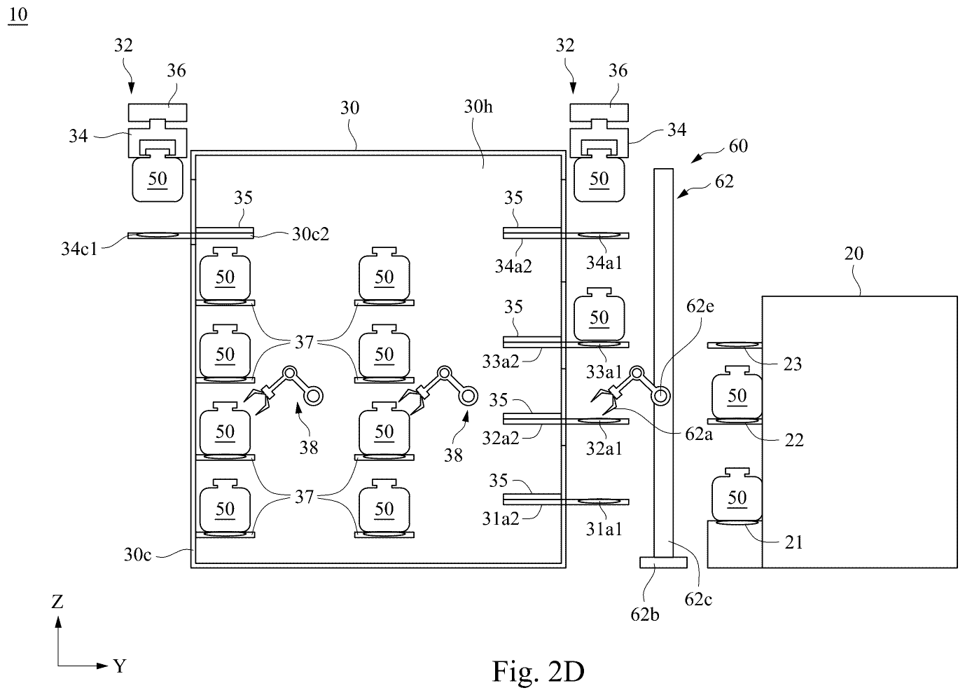

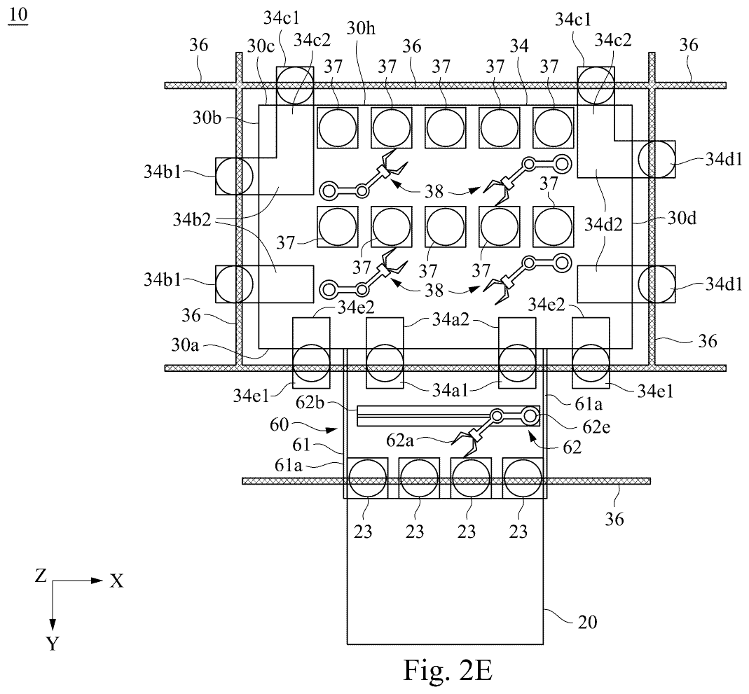

In some embodiments, the fabrication facility 1 includes a network 120 that enables various entities (a fabrication system 130, a metrology device 140, a fault detection and classification (FDC) system 150, a control system 160, an archive data base 170, and another entity 180) to communicate with one another. The network 120 may be a single network or a variety of different networks, such as an intranet, the Internet, another network, or a combination thereof. The network 120 may include wired communication channels, wireless communication channels, or a combination thereof. The FDC system 150 can evaluate conditions in the process tool 20 (see FIGS. 2A-2E), the stocker 30 (see FIGS. 2A-2E), and mechanical components, such as interface module 60 (see FIGS. 2A-2E) to detect abnormalities or faults, by monitoring the data associated the conditions in the mechanical components before, during, and after the transportation process of the wafer containers 50.

The control system 160 can implement control actions in real time. In some embodiments, the control system 160 implements control actions to control the operation status of an overhead transport vehicle (OHT) system 32 in the fabrication system 130. In FIG. 1, the archive database 170 may include a number of storage devices to provide information storage. The information may include raw data obtained directly from the fabrication system 130 (e.g., process tool 20/stocker 30). For example, the information from the process tool 20/stocker 30 may be transferred to the archive database 170 and stored in the archive database 170 for archival purposes. The data from the process tool 20/stocker 30 may be stored in its original form (e.g., as it was obtained from the fabrication system 130) and it may be stored in its processed form (e.g., converted to a digital signal from an analog signal). The archive database 70 stores data associated with the fabrication facility 1.

In some embodiments, the archive database 170 stores data collected from the fabrication system 130, the metrology device 140, the FDC system 150, the control system 160, another entity 180, or a combination thereof. For example, the archive database 170 stores data associated with wafer characteristics of wafers processed by the fabrication system 130 (such as that collected by the metrology device 140 as described below), data associated with parameters implemented by the fabrication system 130 to process such wafers, data associated with analysis of the wafer characteristics and/or parameters of the FDC system 150 and the control system 160, and other data associated with the fabrication facility 1. In some embodiments, the fabrication system 130, the metrology device 140, the control system 160, the FDC system 150, and the other entity 180 may each have an associated database.

Reference is made to FIGS. 2A-2E. FIGS. 2A-2E illustrate schematic views of the OHT system 32 with a stocker 30 and a process tool 20 in accordance with some embodiments of the present disclosure. Specifically, FIG. 2A illustrates a perspective view of the OHT system 32 including vehicles 34 that travel on a track 36 in accordance with some embodiments of the present disclosure. FIG. 2B illustrates a side view of the OHT system 32 including vehicles 34 that travel on a track 36 along a path C1 in FIG. 2A in accordance with some embodiments of the present disclosure. FIGS. 2C and 2D are a side view, an analytical view, and a top view of the process tool 20 combined with the stocker 30 in accordance with some embodiments of the present disclosure. In some embodiments, the vehicle 34 can be interchangeable referred to as a FOUP carrier, and the track 36 can be interchangeable referred to as a carrier orbit.

As shown in FIGS. 2A and 2B, a system 10 can be provided. The system 10 can have at least one process tool 20, at least one stocker 30, and the OHT system 32. The OHT system 32 can be utilized to convey wafer containers 50, which is pre-loaded with wafers, to the designated process tool 20. In some embodiments, the wafer container 50 can be interchangeable referred to as a wafer carrier or a front opening unified pod (FOUP) carrier. The process tool 20 can be characterized as a high-throughput device, such as a lithographic scanner, which may demand that the input rate of wafers aligns with its operational throughput to maximize processing efficiency. Therefore, to match the performance capabilities of the process tool 20, the delivery speed of the wafers via the OHT system 32 is desired to be coordinated with the tool's capacity. This synchronization is to prevent bottlenecks and ensure a smooth workflow. In some embodiments, the process tool 20 can handle more than 250 wafers per hour (WPH) in scenarios involving high-volume manufacturing (HVM). In some embodiments, there are configurations where the process tool's throughput can handle more than 120 WPH when each wafer container 50 holds fewer than 10 wafers, giving the tool's adaptability to different operational demands and its efficiency in processing wafers at a rapid pace.

As shown in FIGS. 2C-2E, the process tool 20 can be equipped with a load port 21, which can serve as the docking station for the wafer container 50 loaded with wafers awaiting processing. Once docked at the load port 21, the wafer container 50 can supply wafers into the process tool 20 for various manufacturing procedures. A limitation may arise from the finite number of load ports 21 available on the process tool 20. Furthermore, not all the wafer containers 50 can be fully loaded at the load ports 21, which affects the overall utilization of the capacity of the process tool 20. The operational efficiency of process tool 20 can be compromised during the transition periods when processed wafer containers 50 are being replaced with unprocessed ones using the OHT system 32, preventing the process tool 20 from being fully productive, as the load port 21 remains idle during these swap intervals. To address this inefficiency, wafers from several partially filled wafer containers 50 (e.g., those containing fewer than 25 wafers) can be consolidated into a single wafer container 50, which in turn allows each wafer container 50 on the load port 21 to deliver a higher number of wafers to the process tool 20, enhancing throughput and reducing the reliance on the OHT system 32 for frequent transports. However, this merging process may introduce additional complexities, such as increased queuing time (Q-time) which could potentially affect wafer quality. Additionally, this merging process may bring about intricate logistics planning to prevent cross-contamination among wafers, considering variables like wafer product type, status, tool specifications, and FOUP (Front Opening Unified Pod) characteristics, contributing to lower merging efficiency and be further constrained by the speed of wafer transport.

This disclosure can enhance the operational efficiency of semiconductor manufacturing, involving an integration of the process tool 20 with the stocker 30, complemented by the installation of additional wafer container slots. Specifically, wafer container slots 22 and 23 can be incorporated into the process tool 20, and wafer container slots 31a1, 32a1, 33a1, and 34a1 can be incorporated into the stocker 30. These slots can be placed at several specific locations on the process tool 20 and the stocker 30 to optimally accommodate the wafer containers 50, facilitating the fastest possible transfer of the wafer containers 50 to and from the process tool 20. By reducing the distance and time it takes for the wafer containers 50 to travel between the stocker 30 and the process tool 20, this arrangement can cut down on the handling time and increase the throughput efficiency of the manufacturing process for maintaining continuous flow and reducing downtime in high-volume production environments. On the other hand, this setup including an increased number of wafer container slots can boost the processing capabilities of the process tool 20. By adding more wafer containers slots, multiple wafer containers 50 can be handled simultaneously, allowing a greater volume of wafers to be processed at once. This capacity expansion not only streamlines the workflow but also accelerates the loading and unloading operations at the load ports 21, thus minimizing idle time and maximizing the use of the process tool.

Therefore, these improvements can address and mitigate the throughput bottlenecks caused by the limited movement speed of wafer FOUP carriers (e.g., vehicles 34) and the restricted number of in-process wafer container slots available on the process tool 20. By increasing the number of accessible wafer container slots and streamlining the transfer of wafers from the stocker 30 to the process tool 20, this configuration effectively elevates the productivity and operational efficiency of high-throughput semiconductor manufacturing environments. Additionally, this approach can alleviate concerns related to queue time (Q-time), which refers to the delay before wafers are processed. By having readily available batches of the same recipe wafers, the process flow can become smoother and faster, minimizing idle times and enhancing throughput. Furthermore, this improved system 10 can retains the original manual maintenance functions of the process tools 20, ensuring that technicians can still perform without any changes to standard operating procedures, allowing for the integration of this new system without disrupting the existing material handling infrastructure.

As shown in FIGS. 2C-2E, an interface module 60 can be installed to enhance the integration between the process tool 20 and the stocker 30. The interface module 60 can serve as a connector that streamlines the movement of the wafer containers 50 between the process tool 20 and the stocker 30. The interface module 60 can include a housing 61 to specify the operational boundaries and the mechanical reach of the interface module 60. Within the housing 61, the interface module 60 can be equipped with at least one transfer module 62 that may boast four degrees of freedom, providing a versatile range of motion for precise and dynamic handling of the wafer containers 50.

From a top view as shown in FIG. 2E, the layout within the housing 61 is can be organized to include specific areas (e.g., footprints) designated for wafer container slots (e.g., wafer container slots 22, 23, 31a1, 32a1, 33a1, and 34a1). These footprints can correspond to locations directly on the process tool 20, encompassing four wafer container slots, and on the stocker 30, encompassing two wafer container slots. This arrangement can ensure a coordinated interface where the transfer module 62 can transfer the wafer containers 50 seamlessly between the wafer container slots. In some embodiments, the transfer module 62 can be implemented as a robotic arm, enhancing ability of the transfer module 62 to handle delicate operations such as the precise positioning and secure transfer of the wafer containers 50. In some embodiments, the transfer module 62 can be interchangeable referred to as a FOUP robot.

As shown in FIGS. 2C-2E, additional wafer container slots 22 and 23 can be integrated directly above the load port 21 of the process tool 20. The wafer container slots 22 and 23 can serve as supplementary staging areas for wafer containers 50, facilitating an efficient workflow within the semiconductor manufacturing process. The wafer container slots 22 and 23 can enable quick and easy access to the wafer containers 50. They can either be pre-loaded with wafers, ready to be immediately transferred to the load port 21 for processing, or used to temporarily hold wafer containers 50 that have just completed processing, such that the time for loading and unloading wafer containers 50 at the load port 21 can be reduced, effectively streamlining the entire operation.

The OHT system 32 can first deposit the wafer container 50 on the topmost wafer container slot (e.g., wafer container slot 23) of the process tool 20. The wafer container slot 23 can be positioned to facilitate easy access and initial staging of the wafer container 50 upon arrival. Once the wafer containers 50 are placed in the topmost wafer container slot, the transfer module 62 then can take over the task of moving the containers 50 from this initial position to other predetermined locations within the process tool 20. This could involve moving the wafer containers 50 to specific load ports 21 where the wafers can be then processed, or to different storage or staging areas (e.g., stocker 30).

In the scenario where all the load ports 21 of the process tool 20 are fully occupied, the operational design can accommodate an efficient standby system for the wafer container 50 using the integrated wafer container slots 22 and 23. Specifically, the wafer container 50, once loaded with wafers and ready for processing, can be transported to either wafer container slot 22 or 23 via the transfer module 62, allowing the wafer container 50 to be staged directly above the load ports 21, optimizing space utilization and reducing the time for subsequent loading steps. Once a load port 21 becomes available, the wafer container 50 can be quickly transitioned from the temporary slot 22 or 23 to the load port 21. This rapid transfer can be facilitated by the transfer module 62, which is designed to move wafer containers 50 efficiently between these specific points. The close proximity of the wafer container slots to the load ports 21 can minimizes the travel distance for the container 50, thereby speeding up the loading process and enhancing the throughput capability of the process tool 20.

After a wafer container 50 has delivered its wafers to the process tool 20 via the load port 21, the load port 21 can be promptly clear to make room for subsequent wafer containers 50 awaiting processing. This can be achieved by relocating the emptied wafer container 50 to designated wafer container slots 22 or 23 (or wafer container slot 31a1, 32a1, 33a1, or 34a1), which are positioned conveniently near the load port 21. This movement can be facilitated by the transfer module 62, which can be designed for efficient, precise transfers within the system 10. Once the processing of the wafers is complete and they need to be collected back into their respective wafer container 50, the wafer container 50 can be quickly brought back from the wafer container slot 22/23 (or wafer container slot 31a1, 32a1, 33a1, or 34a1) to the load port 21 using the transfer module 62, ensuring that the wafers are securely stored back in their container 50 with minimal delay, maintaining the integrity and progression of the manufacturing process. Following the retrieval of the processed wafers, the wafer container 50 can be then moved upward to transfer to the highest designated wafer container slot 23 in readiness for the next phase of its journey, moved into stocker 30 to storage, or moved to the wafer container slot 34b1, 34c1, 34d1, 34e1, or 34a1 for the OHT system 32 to transfer next phase of its journey. Subsequently, the transfer to the next process step can be then executed by the OHT system 32, which carries the wafer container 50 to its new destination within the manufacturing line.

As shown in FIGS. 2C and 2D, the load port 21 and wafer container slots 22 and 23 can be positioned at various vertical elevations, utilizing vertical space within the facility that accommodates multiple wafer containers 50 without extensive horizontal spread. Specifically, the load port 21 can be situated at the first tier, serving as the interface for the process tool 20 where wafer containers 50 are loaded and unloaded. Directly above this, at a higher elevation, is the second tier where the wafer container slot 22 can be located. The wafer container slot 22 can act as a temporary staging area for wafer containers 50 either awaiting processing or just completed, ready to be moved out of the workflow to avoid congestion. The third tier, positioned even higher, can house the wafer container slot 23, which can be used for similar purposes as the wafer container slot 22, further segregating the workflow and enhancing process efficiency by separating storage and processing zones vertically. Furthermore, each tier can support multiple units of its respective component (i.e., load ports or wafer container slots) to expand capacity and adapt to varying operational needs. The number of units (i.e., load ports or wafer container slot) per tier can range from 1 to 8, such as 1, 2, 3, 4, 5, 6, 7, or 8, depending on the specific requirements of the production line.

As shown in FIGS. 2C-2E, the stocker 30 can include a housing 30h made up of sequentially connected sidewalls 30a, 30b, 30c, and 30d. The sidewall 30a, which is positioned close to the process tool 20, can have several wafer container slots installed thereon. The wafer container slots 31a1, 32a1, 33a1, and 34a1 can provide accessible storage right next to the processing area. Specifically, the wafer containers 50 stored in the wafer container slots 31a1, 32a1, 33a1, and 34a1 can be quickly transferred to the load port 21 of the process tool 20. Similarly, once processing is complete, the wafer containers 50 can be swiftly removed from the load port 21 and placed back into these slots 31a1, 32a1, 33a1, and 34a1. This swift removal can help clear the load port 21 quickly for the next batch of wafers, thereby minimizing downtime and maintaining a continuous flow of operations. These wafer container slots 31a1, 32a1, 33a1, and 34a1 can be placed to facilitate the swift movement of wafer containers 50, minimizing the time and distance for transfers. Additionally, the integration of transfer conveyor belts 35 within the stocker 30 can enable the smooth transition of wafer containers 50 from the initial wafer container slots 31a1, 32a1, 33a1, and 34a1 to adjacent wafer container slots 31a2, 32a2, 33a2, 34a2 in the housing 30h. At least one transfer module 38 can be employed to relocate the wafer containers 50 to other designated wafer container slots 37 within the stocker 30. The transfer module 38 is for optimizing the storage layout and accommodating varying production demands. In some embodiments, the transfer module 38 is substantially similar to the transfer module 62 in terms of their structure and operating methods.

In FIGS. 2C and 2D, the stocker 30 can incorporate the wafer container slots 31a1, 32a1, 33a1, and 34a1 arranged at different vertical elevations, allowing for the effective storage and management of multiple wafer containers 50 while minimizing the footprint of the equipment. Specifically, the wafer container slots can be organized into a hierarchical structure of tiers. In some embodiments, the wafer container slot 31a1 can be positioned at the lowest level. In some embodiments, a second tier directly above the first tier, the wafer container slot 32a1 can be positioned, offering additional storage space and facilitating segregated handling of different process batches. In some embodiments, a third tier elevating further, the wafer container slot 33a1 can be positioned. In some embodiments, a fourth tier at the highest level, the wafer container slot 34a1 can be positioned. Each tier can host multiple wafer container slots, enhancing the capacity and flexibility of the stocker 30. Furthermore, each tier can support multiple units of its respective component (i.e., wafer container slots) to expand capacity and adapt to varying operational needs. The number of units (i.e., wafer container slot) per tier can range from 1 to 8, such as 1, 2, 3, 4, 5, 6, 7, or 8, depending on the specific requirements of the production line. This tiered design can not only enhance the organizational aspects of wafer storage but also optimize the physical retrieval and placement processes, reducing the time and motion needed to access any specific wafer container.

In some embodiments, the sidewalls 30a, 30b, 30c, and 30d of the stocker 30 can be utilized to install additional wafer container slots 34e1, 34b1, 34c1, and 34d1. These wafer container slots 34e1, 34b1, 34c1, and 34d1 can be located at the fourth tier, aligning them with the uppermost tier of the wafer container slots such as 34a1. These wafer container slots 34e1, 34b1, 34c1, and 34d1 can hold multiple wafer containers 50, respectively, enhancing the system's flexibility to handle varying volumes of semiconductor production. The capacity of each wafer container slot on the sidewalls of the stocker 30 is variable, with the ability to accommodate between one to eight wafer containers. By way of example and not limitation, each wafer container slots 34e1, 34b1, 34c1, and 34d1 can support multiple units of its respective component (i.e., wafer container slots) to expand capacity and adapt to varying operational needs. The number of units (i.e., wafer container slot) per wafer container slot can range from 1 to 8, such as 1, 2, 3, 4, 5, 6, 7, or 8, depending on the specific requirements of the production line. By adding exterior wafer container slots 31a1, 32a1, 33a1, and 34a1, the stocker can hold a greater number of wafer containers 50, effectively responding to peak production periods without the need for physical expansion of the facility. With wafer container slots 34e1, 34b1, 34c1, and 34d1 positioned at various sides of the stocker, operators can access wafer containers 50 from multiple directions, streamlining workflows and reducing bottlenecks.

The wafer containers 50 can be moved horizontally from initial wafer container slots such as 34e1, 34b1, 34c1, and 34d1 to adjacent wafer container slots 34e2, 34b2, 34c2, and 34d2 in the housing 30h. This movement can be facilitated by the transfer conveyor belts 35. The transfer conveyor belts 35 can ensures that wafer containers 50 can be relocated efficiently to adjacent positions without manual intervention. The wafer containers 50 can be transferred to other suitable wafer containers slots 37 within the stocker 30 using at least one transfer module 38. The transfer module 38 can provide additional flexibility, allowing for vertical or horizontal movements within the framework of the stocker 30, dynamically managing space within the stocker 30 and facilitating easy access to the wafer containers 50. In some embodiments, the stocker 30 is used for storing wafer containers that are immediately processed, as well as providing storage for containers 50 that can be processed at a later time. By providing designated slots for both immediate use and delayed processing, the stocker 30 can acts as a buffer, reducing the congestion at the process tool 20 and ensuring a steady supply of wafers for processing without unnecessary delays.

When the OHT system 32 is utilized to deliver the wafer containers 50 to a stocker 30, the OHT system 32 can first place the wafer containers 50 into the topmost wafer container slot (e.g., wafer container slot 34a1, 34e1, 34b1, 34c1, and 34d1) of the stocker 30. These top wafer container slot can be used as a receiving area, facilitating easy and quick placement by the OHT system 32 which operates in the upper regions of the facility. After the wafer containers 50 are placed in these top wafer container slots, the transfer module 38 within the stocker 30 then can manage the movement of these wafer containers 50 from the initial receiving wafer container slots to other predetermined wafer container slots within the stocker 30.

In the scenario where all the load ports 21 of the process tool 20 are fully occupied, the operational design can accommodate an efficient standby system for the wafer container 50 using the stocker 30. This setup can utilize the OHT system 32, the transfer module 38 within the stocker 30, and/or the transfer module 62 within the interface module 60 to optimize wafer container handling. Specifically, when a wafer container 50, loaded with wafers ready for processing, arrives at a time when no load ports 21 are available, it can be temporarily stationed in the wafer container slot 31a1, 32a1, 33a1, or 34a1. These wafer container slots 31a1, 32a1, 33a1, 34a1, located closer to the processing area, and the wafer container slots 34b1, 34c1, 34d1, 34e1, or 37, which might be slightly farther or positioned differently than the wafer container slots 31a1, 32a1, 33a1, 34a1. For the wafer container 50 placed at the wafer container slots 31a1, 32a1, 33a1, or 34a1, there is an option to either keep them within these slots temporarily or load them directly into the stocker 30 if a prolonged wait is anticipated.

Additionally, for the wafer container 50 placed at the wafer container slots 34b1, 34c1, 34d1, or 34e1, this container 50 can be immediately loaded into the stocker 30 upon placement, and then moved to wafer container slots within the stocker 30 such as the wafer container slot 37, 31a2, 32a2, 33a2, 34a2, 34e2, 34b2, 34c2, or 34d2, to manage space and prepare for processing. Once a load port 21 becomes available, the wafer container 50 is quickly transferred from its temporary slot at the stocker 30 to the load port 21. This swift movement can be facilitated by the transfer module 38 within the stocker 30, and/or the transfer module 62 within the interface module 60. Therefore, the system 10 can be the capability of the wafer container 50 to move from the stocker 30 directly to the load port 21 via the integrated conveyor belt 35 and transfer modules 38 and 62. The system 10 can bypasses the need for the vehicle 34, used for such transfers, thus saving time and reducing the dependency on vehicle availability. This arrangement can ensure that wafer containers 50 can be managed efficiently, keeping them ready for processing without unnecessary delays. It can help maintain a continuous flow in the manufacturing process, optimizing the use of load ports 21 and reducing the bottlenecks associated with wafer supply to the process tool 20. The integration of advanced transfer modules 38 within the stocker 30 and the use of multiple wafer container slots can ensure that production can adapt dynamically to changes in demand and equipment availability.

Once the wafer container 50 has delivered its wafers to the process tool 20 via the load port 21, the load port 20 can be promptly clear to make room for subsequent wafer containers 50 awaiting processing. This can be achieved by relocating the emptied wafer container 50 to designated wafer container slot 37, 31a2, 32a2, 33a2, 34a2, 34e2, 34b2, 34c2, or 34d2 within the stocker 30 to avoid any unnecessary occupancy of the load port 21. The movement can be facilitated by the transfer module 62 and/or transfer module 38. These modules 62 and 38 can ensure that each wafer container 50 can be placed in an appropriate wafer container slot, thereby freeing up the load port 21 while keeping the containers 50 accessible for quick retrieval. Once the processing of the wafers is complete and they need to be collected back into their respective containers 50, the wafer container 50 can be quickly brought back from the wafer container slot 37, 31a2, 32a2, 33a2, 34a2, 34e2, 34b2, 34c2, or 34d2 to the load port 21 using the transfer module 62 and/or transfer module 38, ensuring that the wafers are securely stored back in their container 50 with minimal delay, maintaining the integrity and progression of the manufacturing process. Following the retrieval of the processed wafers, the wafer container 50 can be then moved upward to transfer to the highest designated wafer container slot 23 in readiness for the next phase of its journey. Subsequently, the transfer to the next process step can be then executed by the OHT system 32, which carries the wafer container 50 to its new destination within the manufacturing line. In some embodiments, the wafer container 50 can be moved into the stocker 30 to storage, or moved to the wafer container slot 34b1, 34c1, 34d1, 34e1, or 34a1 for the OHT system 32 to transfer next phase of its journey.

By quickly relocating wafer containers 50 after unloading, the load ports 21 can be kept available for continuous operations, thereby maximizing the usage of processing equipment. Swift movement of containers 50 in and out of the load ports 21 can minimize the cycle time for each batch of wafers, enhancing the overall throughput of the manufacturing process. The use of multiple transfer modules 38 and 62 can provide the flexibility needed to handle various operational demands.

In some embodiments, the system 10 can include a control system 160 in optimizing the operations within the semiconductor manufacturing process. The control system 160 can be configured to oversee and manage the dynamic workflow associated with the handling of wafer containers 50 and the processing of wafers. In some embodiments, the control system 160 can continuously monitor the status of the load ports 21 and the ongoing wafer processing activities within the process tool 20, by archival data stored in the archive database 170. This real-time monitoring can allow for immediate adjustments and decision-making to enhance efficiency and reduce potential bottlenecks.

Specifically, the control system 160 can assess the number and estimated arrival times of wafer containers 50 that are being transported to the process tool 20 via the OHT system 32. This information can be used for planning and sequencing the arrival and processing of wafer batches to ensure a smooth flow and minimal waiting times. Based on the current load port availability and the processing schedule, the control system 160 can determine the optimal placement of each wafer container 50, involving deciding whether to direct a wafer container 50 to the load port 21 or to temporarily store the wafer container 50 at designated wafer container slots (e.g., wafer container slot on the process tool 20 or other wafer container slot on the stocker 30). This decision is based on maximizing the use of the load port 21 and ensuring continuous operation without delays. The control system 160 can utilize the vehicle 34 and the track 36 for precise movements of containers 50 between these locations, ensuring that each wafer container 50 can be positioned efficiently according to the current needs and priorities of the manufacturing process. In some embodiments, a layout includes four tracks 34 arranged in series to encircle the stocker 30. From the top view, these tracks 36 allow vehicles 34 to orbit in a clockwise direction, and they spatially overlap with the wafer container slots on the stocker 30. Additionally, there is another track 34 extending across the wafer container slots on the process tool 20. The motion of the vehicle 34 on this track mirrors the orbit direction of the vehicle on the track closest to the stocker 30, ensuring a coordinated movement pattern around both the stocker 30 and the process tool 20.

In some embodiments, the control system 160 can monitor and decision-making tasks to directly influence wafer container handling within associated stocker 30, enhancing the efficiency and coordination of wafer container movements. Specifically, the control system 160 can directly operate transfer modules 38 and conveyor belts 35 within the stocker 30, allowing the control system 160 to execute movements of the wafer containers 50, and ensuring the wafer containers 50 are accurately positioned for processing or storage. By directly controlling these mechanical components, the control system 160 can streamline the docking and undocking processes on the load port 21 on the process tool 20, which in turn reduces the time wafer containers 50 spend in transit between the stocker 30 and the process tool 20, and minimizing delays and enhancing throughput. Therefore, the ability of the control system 160 to directly interact with the wafer containers handling can allow for quicker responses to changes in production demands or operational conditions, enhancing the agility of the manufacturing process.

As shown in FIGS. 2C-2E, the transfer module 62 in the interface module 60 can be capable of moving the wafer containers 50 among wafer container slots that are on the same level (or tier) within the housing 61, allowing for lateral movement of containers 50 within a defined tier, facilitating easy access to any wafer container located on the same horizontal plane. In some embodiments, the transfer module 62 in the interface module 60 can be equipped to handle the vertical transfer of wafer containers 50 between different tiers within the housing 61 for operations where space optimization across multiple vertical levels is applied. The transfer module 62 may incorporate features like elevators or lift mechanisms for vertical movements and rail systems or conveyor belts for horizontal transfers. The operation of the transfer module 62 can be automated and controlled by software that directs its movements based on real-time data from the control system 160, ensuring that the transfer module 62 operates efficiently, with minimal human intervention, thereby reducing the potential for operational errors.

Specifically, the transfer module 62, integrated within the interface module 60 can include components that coordinate to manipulate and transport wafer containers 50 with high precision across various dimensions and orientations. In some embodiments, the transfer module 62 can include a wafer container gripper 62a for securely holding the wafer container 50 during transit. The gripper can be customized in various shapes and sizes to accommodate different container specifications, ensuring a firm and safe grip without damaging the contents. In some embodiments, the transfer module 62 can further include a linear actuator 62b including a horizontal slide rail and a movable carrier, the linear actuator can facilitate smooth horizontal movements along the rail, and the actuator can power these movements, allowing for precise positioning along the X-axis within the facility. In some embodiments, the transfer module 62 can further include a lifter 62d equipped with a vertical slide rail and a movable carrier operated by an actuator, the lifter can enable vertical movement, allowing the transfer module 62 to adjust the elevation of wafer containers 50, accommodating different tiers within the stocker 30 or aligning with equipment at various heights. In some embodiments, the transfer module 62 can further include a rotor 62e to control the rotational movements of the transfer module 62, enhancing the ability of the wafer container gripper 62a to adjust orientations.

Therefore, the wafer container gripper 62a can move seamlessly in three directions (e.g., horizontally along the X and Y axes and vertically along the Z axis). This multidirectional capability can be used for navigating the layout of semiconductor manufacturing facilities. On the other hand, the transfer module 62 can be capable of omnidirectional movement, achieving a high degree of freedom in operating wafer containers 50. In some embodiments, each component, such as the linear actuator 62b, the lifter 62d, and the rotor 62e in the transfer module 62 can be independently controlled and finely tuned to accelerate or decelerate smoothly. This precise control helps prevent any positional shifts of the wafer containers during rapid movements or transitions, safeguarding the integrity of the wafers.

As shown in FIGS. 2C-2E, the housing 61 of the interface module 60, bridging the process tool 20 and the stocker 30, can include sidewalls 61a, equipped with a window/door mechanism 61b (see FIG. 2C) that serves as both an access point and a safety barrier between the process tool 20 and the stocker 30. The window/door mechanism 61b on the sidewall 61a can be opened by pulling it in a direction perpendicular to the arrangement of the load ports 21 on the process tool 20, allowing easy access while maintaining a clear separation from the operational axis of the load ports, minimizing interference with ongoing processes.

During processing, the window/door mechanism 61b can be locked to ensure safety, activating an interlock system 61c (see FIG. 2C) that prevents accidental opening that could compromise the environment or disrupt the operations within the process tool 20 and the stocker 30. The process tool 20 and the stocker 30 can retain their original safety and manual docking functionalities, enabling manual intervention. Operators can manually unlock the window/door mechanism 61b by pressing an interlock release button 61d (see FIG. 2C). This feature is applied for maintenance, manual loading, or unloading of the wafer containers 50, allowing personnel to intervene without compromising the automated processes. When the interlock release button 61d is pressed, the transfer module 62 within the Interface module 60 can complete its current task and return to a designated home position. This protocol can ensure that all mechanical movements are safely concluded and that the equipment is securely stowed before the window/door is opened for manual access. After completing the manual docking or undocking tasks, personnel can close the window/door mechanism 61b and press the interlock release button 61d to re-engage the lock. This action can reactivate the interlock, securing the area and allowing automated processes to resume safely.

Therefore, the proximity of process tools 20 to the stocker 30 can allow for direct movements of the wafer containers 50, minimizing the delay caused by the vehicles 34 and enhancing the speed of wafer processing. By attaching the process tool 20 to a single stocker 30, the number of in/out ports can be increased, allowing for a greater number of wafer containers 50 to be loaded and unloaded simultaneously for high-throughput environments. The system 10 can allow for tunable wafer container slots 22 and 23, which can be adjusted to accommodate more wafer containers 50 as operational needs grow. Additionally, the system 10 can retain the original vehicle paths for loading and unloading, preserving existing operational practices and minimizing the need for extensive retraining or reconfiguration. Furthermore, the transfer modules 38 and the conveyor belts 35 within the stocker 30 can be directly controlled by the process tools 20, facilitating efficient and precise docking, transferring, and undocking of the wafer containers 50. Despite the high degree of integration and automation, the stockers 30 can maintain their role of storing wafer containers 50, ensuring that wafers are kept securely and are readily accessible.

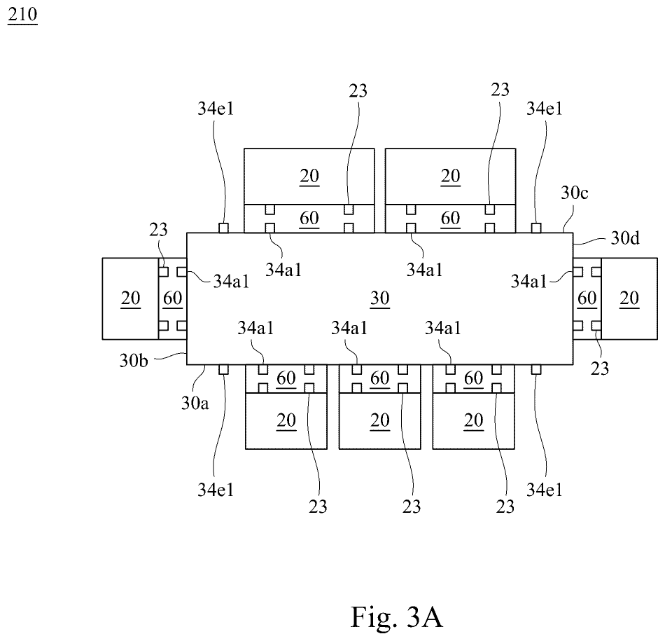

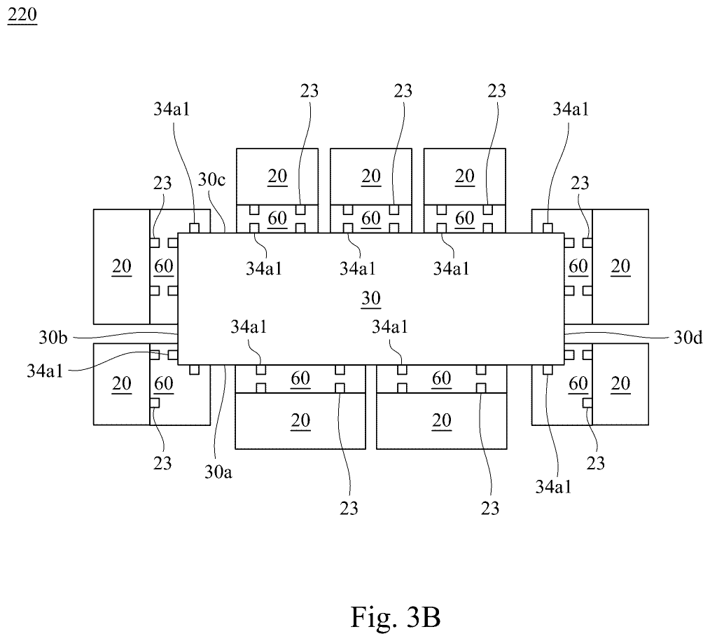

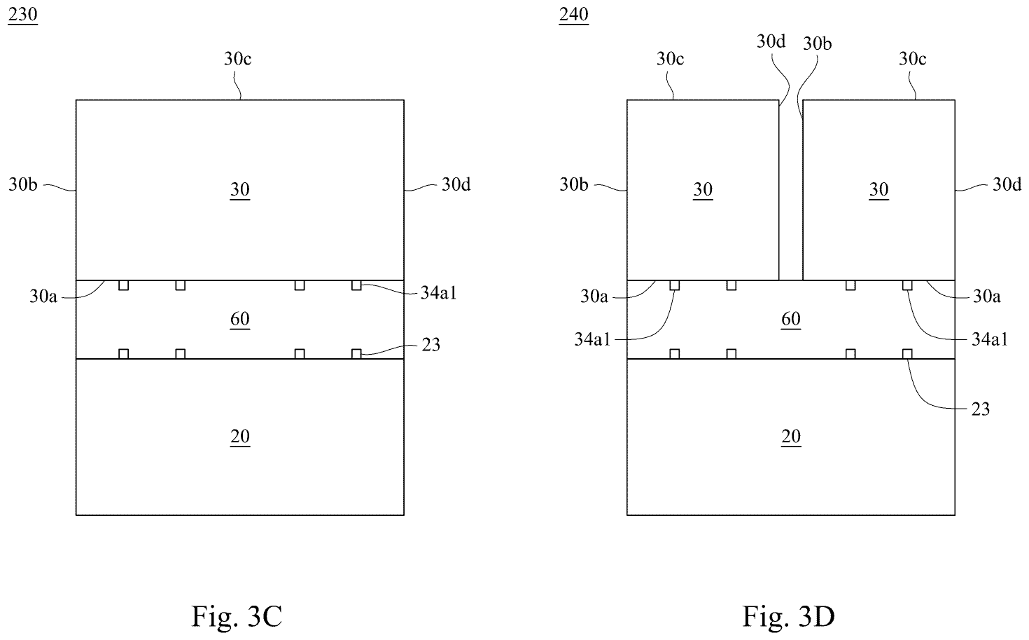

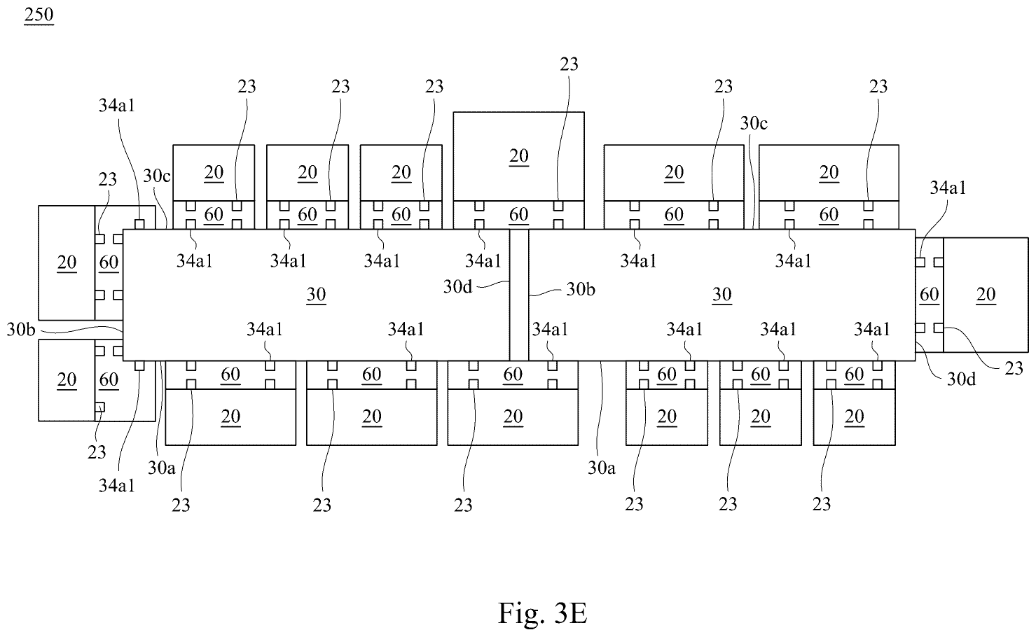

Reference is made to FIGS. 3A-3E. FIGS. 3A-3E illustrate schematic views at least one stocker combined with at least one process tool in accordance with some embodiments of the present disclosure. In some embodiments, the integration of the process tool 20 with the stocker 30 can offer a versatile and scalable integration model for semiconductor manufacturing setups. While FIGS. 3A-3E illustrate embodiments of systems 210, 220, 230, 240, and 250 with different structure configuration than the systems 10 in FIGS. 2A-2E, the present disclosure may repeat reference numerals and/or letters in the various examples. This repetition is for the purpose of simplicity and clarity and does not in itself dictate a relationship between the various embodiments and/or configurations discussed.

As shown in FIGS. 3A and 3B, a single stocker 30 can serve multiple process tools 20. This setup can optimize the utilization of space and resources by allowing several process tools 20 to share a centralized stocker 30 for efficient wafer storage and handling, which in turn supports a cohesive operation where multiple process tools 20 work in tandem, streamlining the workflow and reducing operational delays associated with the handling of wafer containers 50. FIGS. 3A and 3B further illustrate how the multiple process tools 20 can be connected to a single stocker 30. FIG. 3A indicates that each of the sidewalls 30a, 30b, 30c, and 30d of the stocker 30 can accommodate one or more process tools 20 through respective interface modules 60, allowing for flexibility in arranging the process tools 20 around the stocker 30, facilitating direct access and transfer of the wafer containers 50. FIG. 3B indicates that at least two of the sidewalls 30a, 30b, 30c, and 30d of the stocker 30 can simultaneously install a process tool 20 through their respective interface modules 60. This multi-faceted approach can not only maximize the efficiency of wafer container handling but also enhance the throughput capacity.

By using one large stocker 30 to service multiple process tools 20, maximizing the efficiency of wafer storage and handling and reducing the need for multiple individual stockers 30, thereby conserving space and resources while maintaining high throughput levels. Therefore, the shared stocker arrangement can enable rapid and efficient transfer of wafers between the stocker 30 and multiple process tools 20, reducing wait times and improving the overall flow of production. Additionally, the setup (see FIG. 3B) can allow for the efficient use of corner spaces in the stocker 30, where process tools 200 can be placed, maximizing the use of available space. The system 210/220 can be designed to accommodate different types of process tools 200, providing the flexibility to incorporate a variety of process tools 20 that may have different functions and specifications, ensuring that the facility can handle diverse manufacturing requirements.

As shown in FIG. 3C, a one-to-one pairing of a process tool 20 with a stocker 30 can be implemented. This setup can involve integrating a single process tool 20 with one stocker 30, where any one of the sidewalls 30a, 30b, 30c, and 30d of the stocker 30 can be equipped to host the process tool 20 through a designated interface module 60. The stocker 30 can be equipped with tracks 38, allowing for multidirectional movement of wafer container 50, which in turn enhances the flexibility and speed of wafer container transfers within the facility. In some embodiments, the stocker 30 be equipped with an expanded number of wafer container slots, with more than 10 slots available for use, enhancing the capacity for simultaneous loading and unloading operations, accommodating a higher throughput of wafer containers.

As shown in FIG. 3D, multiple stockers 30 can serve a single process tool 20. This configuration can be in scenarios having high-volume outputs or the processing of various types of wafers, offering enhanced organizational flexibility and storage efficiency. The ability to connect one process tool 20 with several stockers 30 can allow for a highly adaptable manufacturing environment. Utilizing multiple stockers 30 with a single process tool 20 can optimize the use of space within the fabrication facility. With multiple stockers 30 at its disposal, a single process tool 20 can operate continuously without downtime caused by storage limitations. Each stocker 30 can be dedicated to different stages of the manufacturing process, such as pre-processing, post-processing, and quality control, thus streamlining the workflow.

As shown in FIG. 3E, multiple stockers 30 can be integrated with multiple process tools 20. This setup can maximize efficiency and flexibility within the production environment, allowing various process tools 20 and stockers 30 to be interconnected and collaboratively manage workloads and resources, allowing for rapid adaptation to changes in production volume or process technology without disruptions. By aligning multiple stockers 30 with multiple process tools 20, the layout can maximize the use of available space within the fabrication facility, minimize wasted space, and enhance the overall efficiency of the fab layout. Additionally, with multiple stockers 30 serving multiple process tools 20, resources such as wafers, chemicals, and storage capacity can be allocated more efficiently across the production floor, ensuring that no single process tool 20 becomes a bottleneck due to resource shortages, thereby smoothing out the production flow. Therefore, by allowing one or more process tools 20 to share one or more stockers 30, the system can dynamically adjust to varying operational scales, enhancing efficiency and throughput in semiconductor manufacturing processes.

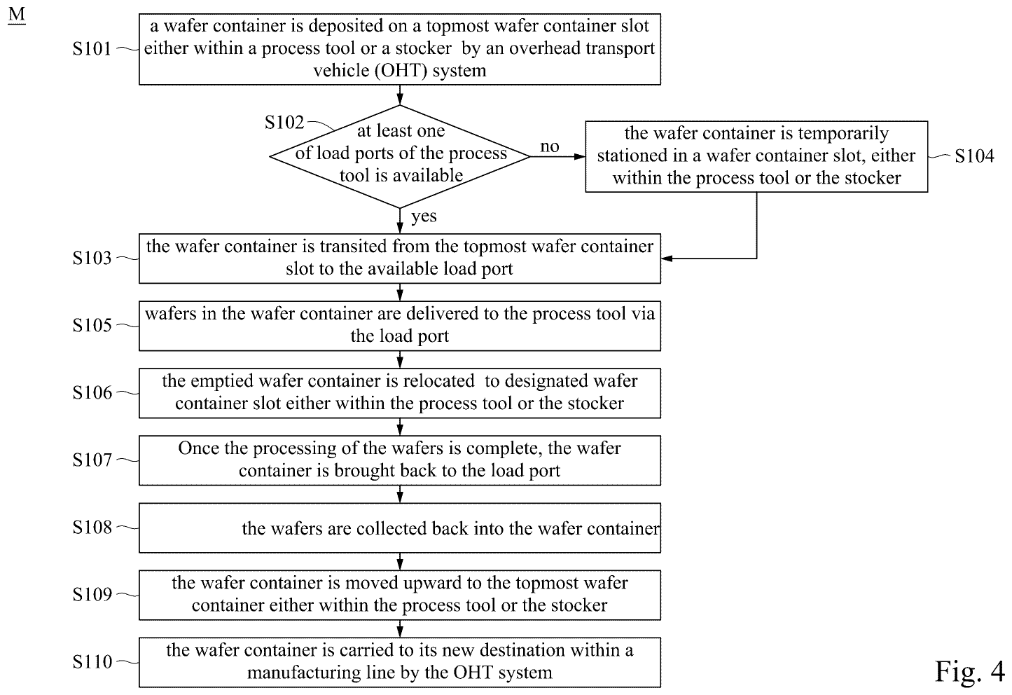

Reference is made to FIG. 4. FIG. 4 is a flowchart of a method M of operating the systems shown in FIGS. 1-3E in accordance with some embodiments of the present disclosure. It is understood that additional operations can be provided before, during, and after the processes shown by FIG. 4, and some of the operations described below can be replaced or eliminated, for additional embodiments of the method. The order of the operations/processes may be interchangeable.

The method M then proceeds to block S101 where a wafer container 50 is deposited on a topmost wafer container slot 23 of a process tool 20 or on a topmost wafer container slot 34a1, 34e1, 34b1, 34c1, or 34d1 of a stocker 30 by an OHT system 23. The topmost wafer container slot can be positioned to facilitate easy access and initial staging of the wafer container 50 upon arrival.

The method M then proceeds to block S102 to determine if at least one load port 21 of the process tool 20 is available. If the determination at block S102 finds an available load port 21, the method M then proceeds to block S103. At block S103, the wafer container 50 is transferred from the topmost wafer container slot to the available load port 21. In the scenario where the wafer container 50 is deposited on the topmost wafer container slot 23 or 34a1, the transfer module 62 then can take over the task of moving the wafer container 50 to specific load port 21 where the wafers can be then processed. In the scenario where the wafer container 50 is deposited on the topmost wafer container slot 34b1, 34c1, 34d1, or 34e1, the transfer module 38 within the stocker 30 then can manage the movement of the wafer container 50 from the initial receiving wafer container slot to other predetermined wafer container slot within the stocker 30, and then the wafer container 50 is transferred from its predetermined wafer container slot at the stocker 30 to the load port 21 by the transfer module 38 within the stocker 30 and the transfer module 62 within the interface module 60.

If all the load ports 21 are not available, the method M then proceeds to block S104. At block S104, the wafer container 50 is temporarily stationed in a wafer container slot, either within the process tool 20 or the stocker 30. In some embodiments, the operational design can accommodate an efficient standby system for the wafer container 50 using the integrated wafer container slot 22/23 or the stocker 30. For example, when a wafer container 50, loaded with wafers ready for processing, arrives at a time when no load ports 21 are available, it can be temporarily stationed in the wafer container slot 34a1, 34a2, 34a3, or 34a4.

The method M then proceeds to block S105 where wafers in the wafer container 50 is delivered to the process tool 20 via the load port 21.

The method M then proceeds to block S106 where the emptied wafer container 50 is relocated to designated wafer container slot of the process tool 20 or the stocker 30. That is, once the wafer container 50 has delivered its wafers to the process tool 20 via the load port 21, the load port 20 can be promptly clear to make room for subsequent wafer containers 50 awaiting processing.

The method M then proceeds to block S107 where once the processing of the wafers is complete, the wafer container 50 is brought back to the load port 21 using the transfer module 62 and/or 38, ensuring that the wafers are securely stored back in their container 50 with minimal delay, maintaining the integrity and progression of the manufacturing process.

The method M then proceeds to block S108 where the wafers are collected back into the wafer container 50.

The method M then proceeds to block S109 where the wafer container 50 is moved upward to the topmost wafer container slot 23 of the process tool 20 or the topmost wafer container slot of the stocker 30 in readiness for the next phase of its journey.

The method M then proceeds to block S110 where the wafer container 50 is carried to its new destination within the manufacturing line by the OHT system 23, which carries the wafer container 50 to its new destination within the manufacturing line.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method to integrate a FOUP stocker with a high-throughput process tool, which can address the long-standing challenges of slow FOUP carrier speeds and insufficient in-process FOUP slots, facilitating direct wafer transfers via conveyor belts or robotic arms, thus bypassing slower carrier systems. The integration can have adjustable FOUP slots that dynamically serve as buffers, adapting in real-time to match production needs, and allows multiple process tools to share FOUP stockers, optimizing space and resources in the facility. Hence, this system can reduce wait times for wafer transfers, increase throughput from more in/out ports, and enhance flexibility with tunable FOUP slots and the ability to quickly supply wafers to process tools. Additionally, the system can maintain more wafers in process, handle different wafer types simultaneously, and allows for a flexible fab layout design.

In some embodiments, a method includes retrieving a first front opening unified pod (FOUP) from a FOUP stocker utilizing an interface module equipped with a transfer module; transporting the retrieved first FOUP via the transfer module across a first path within the interface module to align the first FOUP with an available first load port of a process tool; loading the first FOUP on the first load port; delivering wafers from the first FOUP to the process tool via the first load port to initiate a wafer processing operation using the wafers. In some embodiments, the method further includes before retrieving the first FOUP, transferring the first FOUP to the FOUP stocker utilizing an overhead transport vehicle (OHT) system, wherein the transfer module is positioned lower than the OHT system and situated between the FOUP stocker and the process tool. In some embodiments, the FOUP stocker comprises a plurality of FOUP slots arranged on a sidewall of the FOUP stocker, and the retrieving of the first FOUP comprises selecting the first FOUP from on one of the FOUP slots via the transfer module. In some embodiments, the FOUP slots are arranged vertically along the sidewall of the FOUP stocker. In some embodiments, the method further includes retrieving a second FOUP from one of a plurality of FOUP slot located on a sidewall of the process tool utilizing the interface module equipped with the transfer module. In some embodiments, the method further includes transporting the retrieved second FOUP via the transfer module across a second path within the interface module to align the second FOUP with an available second load port on the process tool. In some embodiments, the FOUP slots are arranged vertically along the sidewall of the process tool. In some embodiments, the method further includes after delivering of the wafers from the first FOUP, relocating the first FOUP to a FOUP slot within the FOUP stocker utilizing the transfer module. In some embodiments, the process tool utilized for the wafer processing operation is a litho-scanner for high-throughput wafer processing. In some embodiments, the transfer module includes a robot arm.

In some embodiments, a method includes loading a first wafer container onto a load port of a process tool; initiating a first wafer processing operation by delivering a plurality of first wafers from the first wafer container to the process tool via the load port; after the delivery of the first wafers, relocating the first wafer container to a first wafer container slot on a stocker, utilizing an interface module equipped with a transfer module; loading a second wafer container onto the load port of the process tool; initiating a second wafer processing operation by delivering a plurality of second wafers from the second wafer container to the process tool via the load port. In some embodiments, the method further includes after the delivery of the second wafers, relocating the second wafer container to a second wafer container slot on the stocker using the interface module equipped with the transfer module. In some embodiments, the method further includes before loading the first wafer container onto the load port, transporting the first wafer container from a second wafer container slot on the stocker to the load port using the transfer module, following a path within the interface module to align the first wafer container with the load port. In some embodiments, the method further includes before loading the first wafer container onto the load port, transporting the first wafer container from a second wafer container slot on the process tool to the load port using the transfer module, following a path within the interface module to align the first wafer container with the load port. In some embodiments, the method further includes before loading the first wafer container onto the load port, transferring the first wafer container to the stocker utilizing an overhead transport vehicle (OHT) system, wherein the transfer module is positioned lower than the OHT system and situated between the stocker and the process tool.

In some embodiments, a system includes a first process tool, a first FOUP stocker, and an first interface module. The first process tool includes a first sidewall, a plurality of first load ports installed on the first sidewall, and a plurality of first front opening unified pod (FOUP) slots installed on the first sidewall and above the first load ports. The first FOUP stocker is positioned adjacent to the first process tool. The first FOUP stocker includes a second sidewall facing the first process tool and a plurality of second FOUP slots installed on the second sidewall. The first interface module is positioned between the first process tool and the first FOUP stocker. The first interface module includes a first housing and a first transfer module within the first housing. From a top view, the first housing of the first interface module encloses the first load ports and the first FOUP slots of the first process tool as well as the second FOUP slots of the first FOUP stocker. In some embodiments, the first FOUP stocker comprises a third sidewall connecting to the second sidewall and a plurality of third FOUP slots installed on the third sidewall, and from the top view, the first housing of the first interface module also encloses the third FOUP slots. In some embodiments, the system further includes a second FOUP stocker positioned adjacent to the first process tool, wherein the second FOUP stocker comprises a third sidewall facing the first process tool and a plurality of third FOUP slots installed on the third sidewall, and from the top view, the first housing of the first interface module also encloses the third FOUP slots. In some embodiments, the system further includes a second process tool positioned adjacent to the first process tool, wherein the second process tool comprises a third sidewall, a plurality of second load ports installed on the third sidewall, and a plurality of third FOUP slots installed on the third sidewall and above the second load ports, and from the top view, the first housing of the first interface module also encloses the second load ports and the third FOUP slots. In some embodiments, the system further includes a second process tool and a second interface module. The second process tool is positioned adjacent to the first FOUP stocker. The second process tool includes a third sidewall, a plurality of second load ports installed on the third sidewall, and a plurality of third FOUP slots installed on the third sidewall and above the second load ports. The second interface module is positioned between the second process tool and the first FOUP stocker. The second interface module includes a second housing and a second transfer module in the second housing. From the top view, the second housing of the second interface module encloses the second load ports of the second process tool.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
retrieving a first front opening unified pod (FOUP) from a FOUP stocker utilizing an interface module equipped with a transfer module;
transporting the retrieved first FOUP via the transfer module across a first path within the interface module to align the first FOUP with an available first load port on a process tool;
loading the first FOUP on the first load port; and
delivering wafers from the first FOUP to the process tool via the first load port to initiate a wafer processing operation using the wafers.

2. The method of claim 1, further comprising:
before retrieving the first FOUP, transferring the first FOUP to the FOUP stocker utilizing an overhead transport vehicle (OHT) system, wherein the transfer module is positioned lower than the OHT system and situated between the FOUP stocker and the process tool.

3. The method of claim 1, wherein the FOUP stocker comprises a plurality of FOUP slots arranged on a sidewall of the FOUP stocker, and the retrieving of the first FOUP comprises selecting the first FOUP from on one of the FOUP slots via the transfer module.

4. The method of claim 3, wherein the FOUP slots are arranged vertically along the sidewall of the FOUP stocker.

5. The method of claim 1, further comprising:
retrieving a second FOUP from one of a plurality of FOUP slot located on a sidewall of the process tool utilizing the interface module equipped with the transfer module.

6. The method of claim 5, further comprising:
transporting the retrieved second FOUP via the transfer module across a second path within the interface module to align the second FOUP with an available second load port on the process tool.

7. The method of claim 5, wherein the FOUP slots are arranged vertically along the sidewall of the process tool.

8. The method of claim 1, further comprising:
after delivering of the wafers from the first FOUP, relocating the first FOUP to a FOUP slot within the FOUP stocker utilizing the transfer module.

9. The method of claim 1, wherein the process tool utilized for the wafer processing operation is a litho-scanner for a high-throughput wafer processing.

10. The method of claim 1, wherein the transfer module includes a robot arm.

11. A method, comprising:
loading a first wafer container onto a load port of a process tool;
initiating a first wafer processing operation by delivering a plurality of first wafers from the first wafer container to the process tool via the load port;
after the delivery of the first wafers, relocating the first wafer container to a first wafer container slot on a stocker, utilizing an interface module equipped with a transfer module;
loading a second wafer container onto the load port of the process tool; and
initiating a second wafer processing operation by delivering a plurality of second wafers from the second wafer container to the process tool via the load port.

12. The method of claim 11, further comprising:
after the delivery of the second wafers, relocating the second wafer container to a second wafer container slot on the stocker using the interface module equipped with the transfer module.

13. The method of claim 11, further comprising:
before loading the first wafer container onto the load port, transporting the first wafer container from a second wafer container slot on the stocker to the load port using the transfer module, following a path within the interface module to align the first wafer container with the load port.

14. The method of claim 11, further comprising:
before loading the first wafer container onto the load port, transporting the first wafer container from a second wafer container slot on the process tool to the load port using the transfer module, following a path within the interface module to align the first wafer container with the load port.

15. The method of claim 11, further comprising:
before loading the first wafer container onto the load port, transferring the first wafer container to the stocker utilizing an overhead transport vehicle (OHT) system, wherein the transfer module is positioned lower than the OHT system and situated between the stocker and the process tool.

16. A system, comprising:
a first process tool comprising a first sidewall, a plurality of first load ports installed on the first sidewall, and a plurality of first front opening unified pod (FOUP) slots installed on the first sidewall and above the first load ports;
a first FOUP stocker positioned adjacent to the first process tool, the first FOUP stocker comprising a second sidewall facing the first process tool and a plurality of second FOUP slots installed on the second sidewall; and
a first interface module positioned between the first process tool and the first FOUP stocker, the first interface module comprising a first housing and a first transfer module within the first housing, wherein from a top view, the first housing of the first interface module encloses the first load ports and the first FOUP slots of the first process tool as well as the second FOUP slots of the first FOUP stocker.

17. The system of claim 16, wherein the first FOUP stocker comprises a third sidewall connecting to the second sidewall and a plurality of third FOUP slots installed on the third sidewall, and from the top view, the first housing of the first interface module also encloses the third FOUP slots.

18. The system of claim 16, further comprising:
a second FOUP stocker positioned adjacent to the first process tool, wherein the second FOUP stocker comprises a third sidewall facing the first process tool and a plurality of third FOUP slots installed on the third sidewall, and from the top view, the first housing of the first interface module also encloses the third FOUP slots.

19. The system of claim 16, further comprising:
a second process tool positioned adjacent to the first process tool, wherein the second process tool comprises a third sidewall, a plurality of second load ports installed on the third sidewall, and a plurality of third FOUP slots installed on the third sidewall and above the second load ports, and from the top view, the first housing of the first interface module also encloses the second load ports and the third FOUP slots.

20. The system of claim 16, further comprising:
a second process tool positioned adjacent to the first FOUP stocker, wherein the second process tool comprises a third sidewall, a plurality of second load ports installed on the third sidewall, and a plurality of third FOUP slots installed on the third sidewall and above the second load ports; and
a second interface module positioned between the second process tool and the first FOUP stocker, wherein the second interface module comprises a second housing and a second transfer module in the second housing, and wherein from the top view, the second housing of the second interface module encloses the second load ports of the second process tool.
